(19) United States
(12) Patent Application Publication
(10) Pub. No.: US 2024/0304770 A1
(43) Pub. Date: Sep. 12, 2024

(54) DISPLAY PANEL, METHOD FOR MANUFACTURING AND DISPLAY DEVICE THEREOF

(71) Applicant: Tianma Advanced Display Technology Institute (Xiamen) Co.,Ltd., Xiamen (CN)

(72) Inventor: Yunyuan ZHANG, Xiamen (CN)

(73) Assignee: Tianma Advanced Display Technology Institute (Xiamen) Co.,Ltd., Xiamen (CN)

(21) Appl. No.: 18/666,984

(22) Filed: May 17, 2024

(30) Foreign Application Priority Data
Oct. 31, 2023 (CN) 202311438725.4

(51) Int. Cl. H01L 33/58; H01L 25/16; H01L 33/62

(52) U.S. Cl. CPC H01L 33/58; H01L 25/167; H01L 33/62

(57) ABSTRACT

A display panel, manufacturing method and display device thereof are described. In an embodiment, the display panel includes: a substrate; a light-emitting device and a compensating structure located on a side of the substrate and located in a display area; and a black adhesive layer located on a side of the substrate and at least filled between the adjacent light-emitting devices and between the adjacent position supplementing structure and light-emitting device. The present disclosure can be used to improve the coverage uniformity of the black adhesive layer and improve the display uniformity.

### CROSS-REFERENCE TO RELATED DISCLOSURE

The present disclosure claims priority to Chinese Patent Application No. 202311438725.4, filed on Oct. 31, 2023, the content of which is incorporated herein by reference in its entirety.

### TECHNICAL FIELD

This disclosure is related to display technology and in particular to display devices, display panels, and methods of manufacturing them.

### BACKGROUND

Light-emitting diodes (LEDs) have advantages of self-luminousity, high brightness, long life, low power consumption, fast response speed, etc., and have been widely used in the display field. LEDs cannot be directly manufactured on a driving substrate, and an existing micro-LED or mini-LED display panel usually uses a mass transfer technology to transfer LEDs to the driving substrate for bonding. At present, LED display panels have a problem of poor display uniformity.

### SUMMARY

Aspects of the present disclosure provide a display panel, a manufacturing method and a display device thereof to solve the problem of poor display uniformity in the prior art.

In a first aspect, an embodiment of the present disclosure provides a display panel, the display panel includes:

a substrate;

a light-emitting device and a compensating structure located on a side of the substrate

and located in the display area;

a black adhesive layer located on a side of the substrate, the black adhesive layer is at least filled between adjacent light-emitting devices and between the adjacent compensating structure and light-emitting device.

In a second aspect, based on the same or similar inventive concepts, an embodiment of the present disclosure provides a method for manufacturing a display panel, the display panel includes a light-emitting device and a compensating structure; and the manufacturing method includes:

transferring at least part of the light-emitting device on a side of the substrate;

detecting a brightness of the light-emitting device and determining the compensation

position;

manufacturing a corresponding compensating structure according to the compensation position;

forming a black adhesive layer, wherein the black adhesive layer is at least filled between the adjacent light-emitting devices and between the adjacent compensating structure and light-emitting device.

In a third aspect, the embodiments of the present disclosure provide a display device. In an embodiment, the display device includes a display panel. In an embodiment, the display panel includes: a substrate; a light-emitting device and a compensating structure located on a side of the substrate and located in the display area; a black adhesive layer located on a side of the substrate, the black adhesive layer is at least filled between adjacent light-emitting devices and between the adjacent compensating structure and light-emitting device.

### BRIEF DESCRIPTION OF DRAWINGS

In order to make the technical solutions according to the embodiments of the disclosure or in the prior art more apparent, the drawings to which the embodiments or the prior art is described with reference will be introduced below in brief, and apparently the drawings to be described below are only some embodiments of the disclosure, and those ordinarily skilled in the art can further drive from these drawings other drawings without any inventive effort.

FIG. 1 is a schematic diagram of a display panel according to an embodiment of the present disclosure;

FIG. 2 is a schematic cross-sectional view at line A-A′ in FIG. 1 according to an embodiment of the present disclosure;

FIG. 3 is a flowchart of a method for manufacturing a display panel according to an embodiment of the present disclosure;

FIG. 4 is another schematic diagram of a display panel according to an embodiment of the present disclosure;

FIG. 5 is a schematic cross-sectional view at line B-B′ in FIG. 4 according to an embodiment of the present disclosure;

FIG. 6 is a partial schematic diagram of a driving substrate according to an embodiment of the present disclosure;

FIG. 7 is a schematic diagram of another display panel according to an embodiment of the present disclosure;

FIG. 8 is a flowchart of a method for manufacturing another display panel according to an embodiment of the present disclosure;

FIG. 9 is a partial schematic diagram of another display panel according to an embodiment of the present disclosure;

FIG. 10 is a schematic diagram of another display panel according to an embodiment of the present disclosure;

FIG. 11 is a partial schematic diagram of another display panel according to an embodiment of the present disclosure;

FIG. 12 is a schematic diagram of another display panel according to an embodiment of the present disclosure;

FIG. 13 is a partial schematic diagram of another display panel according to an embodiment of the present disclosure;

FIG. 14 is a partial schematic diagram of another display panel according to an embodiment of the present disclosure;

FIG. 15 is a schematic cross-sectional view of another display panel according to an embodiment of the present disclosure;

FIG. 16 is a schematic cross-sectional view of another display panel according to an embodiment of the present disclosure;

FIG. 17 is a schematic cross-sectional view of another display panel according to an embodiment of the present disclosure;

FIG. 18 is a schematic cross-sectional view of another display panel according to an embodiment of the present disclosure;

FIG. 19 is a schematic cross-sectional view of another display panel according to an embodiment of the present disclosure;

FIG. 20 is a schematic diagram of a display panel according to an embodiment of the present disclosure;

FIG. 21 is a schematic diagram of a display device according to an embodiment of the present disclosure.

### DESCRIPTION OF EMBODIMENTS

In order to make the purpose, technical solutions and advantages of the embodiments of the present disclosure clearer, the technical solutions in the embodiments of the present disclosure will be described clearly and completely below in conjunction with the accompanying drawings in the embodiments of the present disclosure, and it is clear that the embodiments described are some embodiments of the embodiments of the present disclosure, rather than all embodiments of the present disclosure. Based on the embodiments in the present disclosure, all other embodiments obtained by those of normal skill in the art fall within the scope of protection of the present disclosure.

Terms used in the embodiments of the present disclosure are only for the purpose of describing specific embodiments, but not intended to limit the present disclosure. The singular forms of “a”, “an” and “the” used in the embodiments of the present disclosure and the appended claims are also intended to indicate plural forms, unless clearly indicating others.

It should be understood that although a XX may be described using the terms of “first”, “second”, etc., in the embodiments of the present disclosure, the XX will not be limited to these terms. These terms are used only to distinguish the XX from each other. For example, without departing from the scope of the embodiments of the present disclosure, the first XX may also be referred to as the second XX, and similarly, the second XX may also be referred to as the first XX.

When manufacturing the display panel, a driving layer is firstly manufactured on a substrate to form a driving substrate, an LED is transferred to a specific position on the driving substrate by adopting a transfer process, and then the substrate is blackened by adopting a black glue filling method to obtain an integral black appearance. However, the display panel obtained by this process has a problem of poor display uniformity. The applicants found the reason for poor display uniformity by the study and analyze of the structure of the display panel. In order to ensure the yield of the display panel, the display panel needs to be lightened and tested before leaving the factory. When the LED has a brightness defect, the LED is transferred and repaired at the redundant position of the sub-pixel to ensure that the sub-pixel can emit light normally. The position of the repaired sub-pixel includes the LED transferred for the first time and the repaired LED, while the position of the sub-pixel which does not need to be repaired includes only the LED transferred for the first time, and there is no repaired LED at its redundant position, which results in uneven distribution of LEDs on the substrate. Due to the influence of surface tension, the black glue is relatively more gathered in the area where the LEDs are distributed, and the black glue can well cover the substrate. However, in an area with less LED distribution, the amount of black glue is less, and the black glue cannot cover the substrate well, resulting in the problem of uneven coverage of the black glue. The uneven coverage of the black glue in the display panel results in poor display uniformity.

In order to solve the problems existing in the related art, an embodiment of the present disclosure provides a display panel, which is provided with a compensating structure on the same side of the substrate as the light-emitting device, and the problem of uneven distribution of the light-emitting device on the display panel is compensated by using the compensating structure. Both the compensating structure and the light-emitting device belong to the convex structure on the substrate before the black adhesive layer is deposited, and the arrangement uniformity of the in-plane convex structure can be improved by providing the compensating structure. When manufacturing the black adhesive layer, the black glue material can be gathered around the light-emitting device under the influence of surface tension in the flowing process, and can also be gathered around the compensating structure, so that the black glue can be relatively uniformly covered between the compensating structure and the light-emitting device and between adjacent light-emitting devices, and the problem of uneven display caused by uneven coverage of the black glue can be improved.

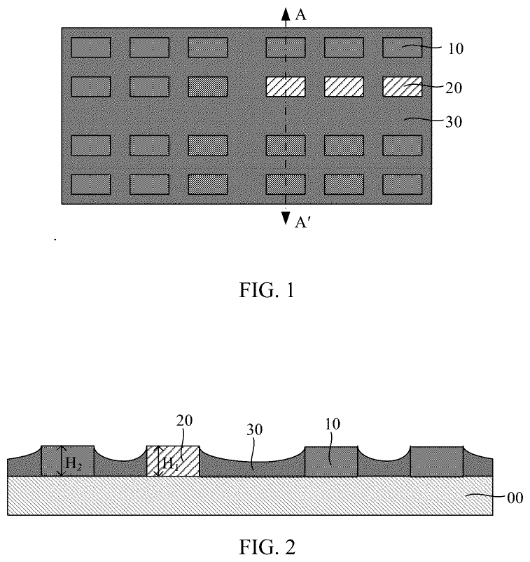

FIG. 1 is a partial schematic diagram of a display panel according to some embodiments of the present disclosure, and FIG. 2 is a cross-sectional view taken along line A-A′ in FIG. 1 according to some embodiments of the present disclosure. FIG. 1 only shows a partial area of the display panel, and the arrangement of light-emitting devices in the display panel is only schematically represented. Combining FIG. 1 and FIG. 2, the display panel includes a substrate 00, a light-emitting device 10, a compensating structure 20 and a black adhesive layer 30, the light-emitting device 10 and the compensating structure 20 are located in the display area and on the same side of the substrate 10, and the compensating structure 20 and the light-emitting device 10 have different structures. The light-emitting device 10 is a light-emitting diode (LED), such as a micro-LED, a mini-LED, or a nano-LED. The compensating structure 20 is provided to fill the position of the vacant light-emitting device 10, and cannot emit light. The position of the vacant light-emitting device 10 means that the distribution uniformity of the light-emitting device 10 in the display area is affected because the light-emitting device 10 is not provided at the position. The black adhesive layer 30 is located on a side of the substrate 00, and the black adhesive layer 30 is filled at least between adjacent light-emitting devices 10 and between the adjacent compensating structure 20 and light-emitting device 10. The substrate is blackened by using the black adhesive layer 30 to finally present an integral black appearance.

Assuming that the compensating structure 20 is not provided in FIG. 2, the distance between the two light-emitting devices 10 on the left and right sides of the compensating structure 20 is relatively large, and when manufacturing the black adhesive layer 30, the black glue material has a certain fluidity, and the black glue material may be gathered around the light-emitting devices 10 under the influence of surface tension, so that the black glue material in the middle area between the two light-emitting devices 10 is relatively thin and even does not have black glue coverage, thereby resulting in uneven coverage of the black adhesive layer 30 and affecting the display contrast. However, in the embodiment of the present disclosure, the compensating structure 20 is provided, the distance between the compensating structure 20 and the light-emitting devices 10 on the left and right sides thereof is not too large, and the black glue material may be gathered around the compensating structure 20 under the influence of surface tension, thereby improving the coverage uniformity of the black adhesive layer 30.

According to the display panel provided by the embodiments of the present disclosure, the compensating structure 20 is provided on the same side of the substrate 00 as the light-emitting device 10, and the compensating structure 20 can fill the position of the vacant light-emitting device 10 in the display area to compensate the problem of uneven distribution of the light-emitting device 10. Both the compensating structure 20 and the light-emitting device 10 belong to the convex structure on the substrate before the black adhesive layer 30 is deposited, and the arrangement uniformity of the in-plane convex structure can be improved by providing the compensating structure 20. When manufacturing the black adhesive layer 30, the black glue material can be gathered around the light-emitting device 10 and around the compensating structure 20 under the influence of surface tension in the flowing process, so that the black adhesive layer 30 can be relatively uniformly covered between the compensating structure 20 and the light-emitting device 10 and between adjacent light-emitting devices 10, thereby improving the problem of uneven display caused by uneven coverage of the black glue.

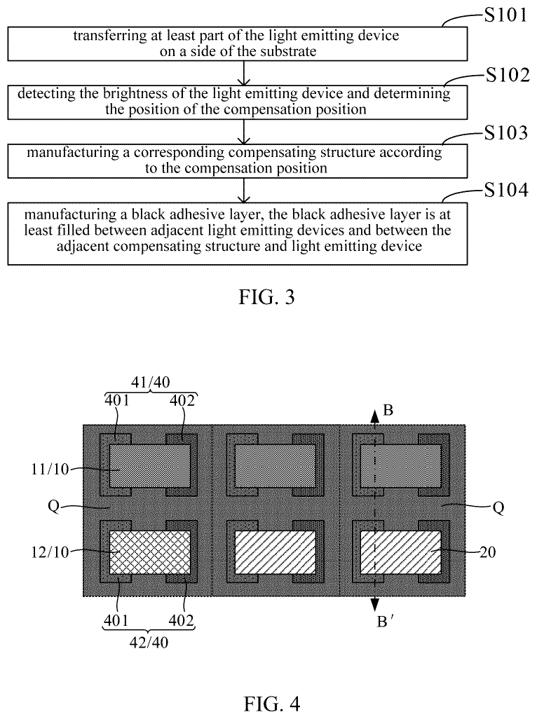

Based on the same inventive concept, an embodiment of the present disclosure further provides a method for manufacturing a display panel, which can be used to manufacture the display panel provided by the embodiments of the present disclosure. FIG. 3 is a flowchart of a method for manufacturing a display panel according to an embodiment of the present disclosure. As shown in FIG. 3, the manufacturing method of the display panel includes:

Step S101: transferring at least part of the light-emitting device 10 on a side of the substrate;

Step S102: detecting the brightness of the light-emitting device 10 and determining the position of the compensation position; for example, the compensation position is the position of the vacant light-emitting device in the display area;

Step S103: manufacturing a corresponding compensating structure 20 according to the compensation position; and

Step S104: manufacturing a black adhesive layer 30, the black adhesive layer 30 is at least filled between adjacent light-emitting devices 10 and between the adjacent compensating structure 20 and light-emitting device 10.

According to the manufacturing method provided by the embodiments of the present disclosure, after transferring at least part of the light-emitting devices 10, the compensating structure 20 is manufactured according to the compensation position, and the compensating structure 20 does not affect the transfer yield of the light-emitting devices 10, and the compensating structure 20 can compensate the problem of uneven distribution of the light-emitting devices 10 in the display area. When manufacturing the black adhesive layer 30, the black glue material can be gathered around the light-emitting device 10 and the compensating structure 20 under the influence of surface tension in the flowing process, so that the black adhesive layer 30 can be relatively uniformly covered between the compensating structure 20 and the light-emitting device 10 and between adjacent light-emitting devices 10, thereby improving the problem of uneven display caused by uneven coverage of the black glue.

As shown in FIG. 2, the vertical distance between the surface of the side of the compensating structure 20 away from the substrate 00 and the substrate 00 is H1, and the vertical distance between the surface of the side of the light-emitting device 10 away from the substrate 00 and the substrate 00 is H2, H1≤H2. In other words, with the plane where the substrate 00 is located as a reference plane, the height of the compensating structure 20 is smaller than or equal to the height of the light-emitting device 10. That is, the height of the compensating structure 20 is not higher than that of the light-emitting device 10. In this way, the compensating structure 20 does not affect the overall thickness of the display panel.

In some embodiments, FIG. 4 is a schematic diagram of another display panel according to an embodiment of the present disclosure. As shown in FIG. 4, the display panel includes an electrode unit 40 provided on a side of the substrate 00, the electrode unit 40 includes a main electrode unit 41 and a redundant electrode unit 42. The light-emitting device 10 includes a main light-emitting device 11, the main light-emitting device 11 is connected to the main electrode unit 41. FIG. 4 is a schematic top view of a display panel, and the top view direction is parallel to a direction perpendicular to a plane where the substrate 00 is located. As can be seen from FIG. 4, along a direction perpendicular to the plane where the substrate 00 is located, the compensating structure 20 at least partially overlaps with the redundant electrode unit 42.

In FIG. 4, one main electrode unit 41 is correspondingly provided with one redundant electrode unit 42. The area where the main electrode unit 41 and the corresponding redundant electrode unit 42 are located may be considered as a pixel region Q (in dotted line), the main electrode unit 41 and the redundant electrode unit 42 in one pixel region Q share a pixel circuit, and the pixel circuit is provided to drive the light-emitting device 10 in the display panel to emit light. In some other embodiments, a pixel region Q is provided with two or more main electrode units 41 and two or more redundant electrode units 42. The redundant electrode unit 42 is used as a substitute for the main electrode unit 41 when the main light-emitting device 11 emits light abnormally due to connection or failure of the main light-emitting device 11, that is, compensating the abnormal main light-emitting device 11 by connecting a new light-emitting device 10 to the redundant electrode unit 42. In this case, the light-emitting device 10 connected to the redundant electrode unit 42 may be considered as a repair light-emitting device, or referred to as a redundant light-emitting device 12. The redundant electrode unit 42 and the redundant light-emitting device 12 are located at redundant positions corresponding to the main light-emitting device 11. FIG. 4 shows that some pixel regions Q include a main light-emitting device 11 and a compensating structure 20, and some pixel regions Q include a main light-emitting device 11 and a redundant light-emitting device 12. When two or more light-emitting devices 10 are included in one pixel region Q, the light-emitting materials of the light-emitting devices 10 in the pixel region Q are the same.

In addition, it should be noted that the electrode unit 40 is a concept of an electrode pair, that is, the main electrode unit 41 and the redundant electrode unit 42 respectively include a first electrode 401 and a second electrode 402, one of the first electrode 401 and the second electrode 402 is an anode electrode, and the other is a cathode electrode. The two electrodes of the light-emitting device 10 are electrically connected to the two electrodes of the electrode unit 40 correspondingly, so that the light-emitting device 10 is bound to the electrode unit 40.

In the embodiments of the present disclosure, the light-emitting device 10 may be a front-mounted LED, a flip-chip LED, or a vertical LED.

It can be understood that, in a solution in which the display panel includes the main electrode unit 41 and the redundant electrode unit 42, when the redundant electrode unit 42 does not replace the main electrode unit 41 to work, the position where the redundant electrode unit 42 is located does not need to be provided with a light-emitting device, and then the position where the redundant electrode unit 42 is located forms the position of the vacant light-emitting device. Some of the redundant electrode units 42 are connected to the redundant light-emitting devices 12, and some of the redundant electrode units 42 are not connected to the light-emitting devices 10, thereby causing a problem of uneven distribution of the light-emitting devices 10 in the display panel.

In the embodiments of the present disclosure, the compensating structure 20 is at least partially overlaps with the redundant electrode unit 42, and the compensating structure 20 is provided at the redundant position of the unrepaired light-emitting device, which can compensate the problem of uneven distribution of the light-emitting device 10. When manufacturing the black adhesive layer 30, the black glue material can be gathered around the light-emitting device 10 and the compensating structure 20 under the influence of surface tension in the flowing process, so that the black adhesive layer 30 can be relatively uniformly covered between the compensating structure 20 and the light-emitting device 10 and between adjacent light-emitting devices 10, thereby improving the problem of uneven display caused by uneven black glue coverage.

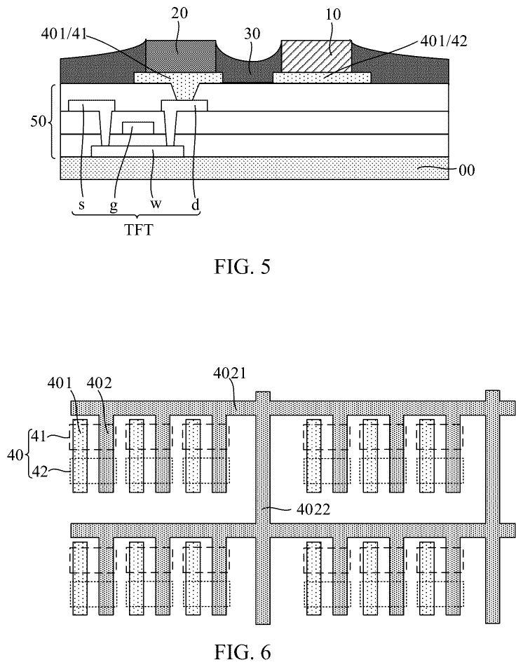

FIG. 5 is a schematic cross-sectional view at line B-B′ in FIG. 4. As shown in FIG. 5, the display panel includes a driving layer 50 located on the substrate 00, the driving layer 50 includes a transistor TFT, and the main electrode unit 41 and the redundant electrode unit 42 are located on the driving layer 50. The transistor TFT includes an active layer w, a grid electrode g, a source electrode s and a drain electrode d, the pixel circuit is made of multiple transistors TFTs. A driving substrate is made of a substrate 00 and a driving layer 50. In FIG. 5, the first electrode 401 in the main electrode unit 41 is connected to the drain electrode d of the transistor TFT. Optionally, the first electrode 401 in the redundant electrode unit 42 and the first electrode 401 in the main electrode unit 41 are electrically connected to form a co-electrode, and the main electrode unit 41 and the redundant electrode unit 42 in one pixel region Q are connected to a same pixel circuit.

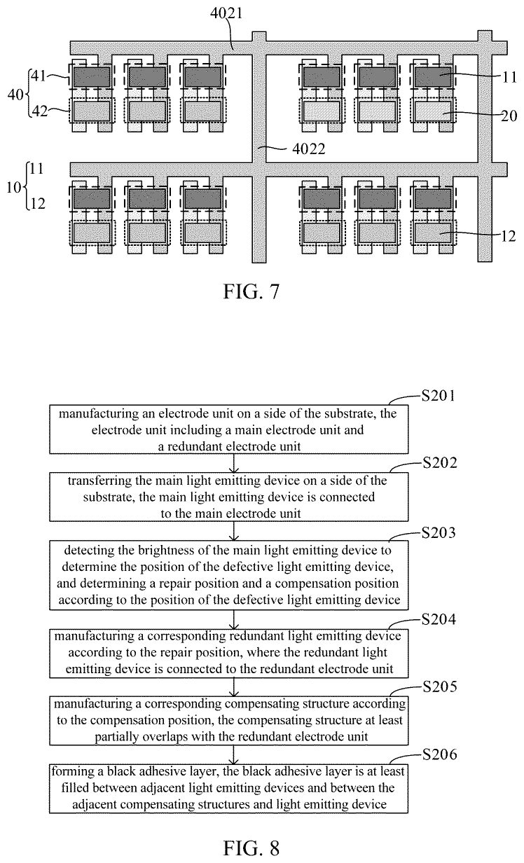

In some embodiments, FIG. 6 is a partial schematic diagram of a driving substrate according to an embodiment of the present disclosure, and FIG. 7 is a schematic diagram of another display panel according to an embodiment of the present disclosure. For a film layer structure of the driving substrate, refer to FIG. 5. As shown in FIG. 6, the driving substrate includes an electrode unit 40, and the electrode unit 40 includes a main electrode unit 41 and a redundant electrode unit 42. The main electrode unit 41 and the redundant electrode unit 42 respectively include a first electrode 401 and a second electrode 402, one of which is an anode electrode and the other is a cathode electrode. In addition, the driving substrate is provided with a first electrode line 4021 and a second electrode line 4022 intersecting with each other and electrically connected to each other, the second electrode 402 is electrically connected to the first electrode line 4021, the first electrode line 4021 and the second electrode line 4022 form a mesh co-electrode, the first electrode 401 is electrically connected to a pixel circuit in the driving substrate, and the second electrode 402 is electrically connected to the first electrode line 4021. The relative positions of the main electrode units 41 and the redundant electrode units 42 in the driving substrate are fixed, and one main electrode unit 41 is correspondingly provided with one redundant electrode unit 42 in FIG. 6. The driving substrate includes a substrate 00 and a driving layer, and the electrode unit 40 is located on the driving layer.

As shown in FIG. 7, the display panel includes the driving substrate shown in FIG. 6. In the display panel, the main light-emitting device 11 is connected to the main electrode unit 41, the compensating structure 20 at least partially overlaps with the redundant electrode unit 42, and the redundant light-emitting device 12 is connected to the redundant electrode unit 42.

The arrangement of the light-emitting devices 10 in FIG. 7 is merely illustrative and is not intended to limit the present disclosure.

In some embodiments, FIG. 8 is a flowchart of a method for manufacturing another

display panel according to an embodiment of the present disclosure. As shown in FIG. 8, the manufacturing method of the display panel includes:

Step S201: manufacturing an electrode unit 40 on a side of the substrate, the electrode unit 40 including a main electrode unit 41 and a redundant electrode unit 42;

Step S202: transferring the main light-emitting device 11 on a side of the substrate, the main light-emitting device 11 is connected to the main electrode unit 41;

Step S203: detecting the brightness of the main light-emitting device 11 to determine the position of the defective light-emitting device, and determining a repair position and a compensation position according to the position of the defective light-emitting device; the repair position is a position where the redundant electrode unit 42 that needs to work with the replacement main electrode unit 41 is located, and the position where the redundant electrode unit 42 that does not need to work with the replacement main electrode unit 41 is located is the compensation position;

Step S204: manufacturing a corresponding redundant light-emitting device 12 according to the repair position, where the redundant light-emitting device 12 is connected to the redundant electrode unit 42; so that the redundant light-emitting device 12 can replace the main light-emitting device 11 with the brightness defect to emit light;

Step S205: manufacturing a corresponding compensating structure 20 according to the compensation position, the compensating structure 20 at least partially overlaps with the redundant electrode unit 42. The manufacturing sequence of steps S204 and S205 may be interchanged

Step S206: forming a black adhesive layer 30, the black adhesive layer 30 is at least filled between adjacent light-emitting devices 10 and between the adjacent compensating structures 20 and light-emitting device 10.

Embodiments of the present disclosure provide a manufacturing method, in which a main electrode unit 41 and a redundant electrode unit 42 are manufactured in a display panel, and when a main light-emitting device 11 connected to the main electrode unit 41 cannot emit light normally, a position of a defective light-emitting device is determined according to a condition that the defective light-emitting device cannot emit light normally, thereby determining a repair position and a compensation position. A redundant light-emitting device 12 is connected to the redundant electrode unit 42 at the repair position, and the redundant light-emitting device 12 replaces the main light-emitting device 11 to emit light. The compensating structure 20 is manufactured at the compensation position, and the problem of uneven distribution of the light-emitting devices 10 in the display area is compensated by using the compensating structure 20. When manufacturing the black adhesive layer 30, the black glue material can be gathered around the light-emitting device 10 and the compensating structure 20 under the influence of surface tension in the flowing process, so that the black adhesive layer 30 can be relatively uniformly covered between the compensating structure 20 and the light-emitting device 10 and between adjacent light-emitting devices 10, thereby improving the problem of uneven display caused by uneven coverage of the black glue.

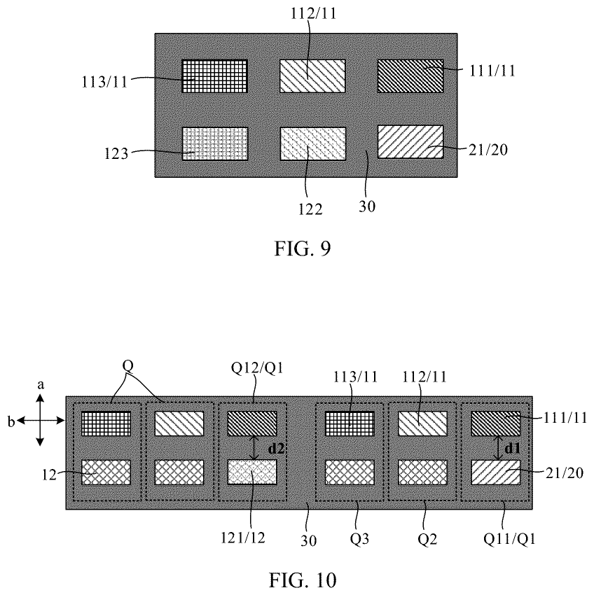

In some embodiments, FIG. 9 is a partial schematic diagram of another display panel according to an embodiment of the present disclosure, as shown in FIG. 9, the compensating structure 20 includes a first compensating structure 21, and the main light-emitting device 11 includes a first main light-emitting device 111. The first compensating structure 21 is adjacent to the first main light-emitting device 111. The orthographic projection area of the first compensating structure 21 on the substrate is equal to the orthographic projection area of the first main light-emitting device 111 on the substrate. FIG. 9 is a top view of a display panel, and it can be understood that in the top view, the main light-emitting device 111 and its orthographic projection on the substrate overlaps, and in the top view, the first compensating structure 21 and its orthographic projection on the substrate overlaps. In the following embodiments related to orthographic projection, the orthographic projection may also be understood with reference to the foregoing description.

In the embodiment of the present disclosure, the orthographic projection area of the first compensating structure 21 on the substrate is equal to the orthographic projection area of the first main light-emitting device 111 on the substrate, that is, the occupied area of the first compensating structure 21 is the same as the occupied area of the first main light-emitting device 111. The first compensating structure 21 can be filled in a redundant position corresponding to the first main light-emitting device 111 where no repairing light-emitting device is provided. In the manufacturing process of the black adhesive layer 30, the flowability of the black glue material around the first compensating structure 21 is more similar to the flowability of the black glue material around the first main light-emitting device 111, thereby improving the uniformity of the whole surface coverage of the black adhesive layer 30 and improving the display contrast.

As shown in FIG. 9, an orthographic projection shape of the first compensating structure 21 on the substrate is the same as an orthographic projection shape of the first main light-emitting device 111 on the substrate, and the first compensating structure 21 is similar to the first main light-emitting device 111. In the manufacturing process of the black adhesive layer 30, the flowability of the black glue material around the first compensating structure 21 is substantially the same as the flowability of the black glue material around the first main light-emitting device 111, thereby further improving the uniformity of the whole surface coverage of the black adhesive layer 30 and improving the display contrast.

In addition, as shown in FIG. 9, the main light-emitting device 11 further includes a second main light-emitting device 112 and a third main light-emitting device 113, the first main light-emitting device 111, the second main light-emitting device 112 and the third main light-emitting device 113 contain different light-emitting materials. The display panel includes a second redundant light-emitting device 122 and a third redundant light-emitting device 123, a light-emitting material of the second redundant light-emitting device 122 is the same as a light-emitting material of the second main light-emitting device 112, and light-emitting materials of the third redundant light-emitting device 123 and the third main light-emitting device 113 are the same. The second redundant light-emitting device 122 is a repair light-emitting device of the second main light-emitting device 112, and the third redundant light-emitting device 123 is a repair light-emitting device of the third main light-emitting device 113.

In some embodiments, FIG. 10 is a schematic diagram of another display panel according to an embodiment of the present disclosure, as shown in FIG. 10, the redundant light-emitting device 12 includes a first redundant light-emitting device 121, and a light-emitting material of the first redundant light-emitting device 121 is the same as a light-emitting material of the first main light-emitting device 111. The display panel is divided into a plurality of pixel regions Q, and the pixel region Q at least includes a plurality of first color pixel regions Q1, second color pixel regions Q2 and third color pixel regions Q3. The first color pixel region Q1, the second color pixel region Q2 and the third color pixel region Q3 constitute a pixel unit capable of displaying white.

The first color pixel region Q1 includes a first pixel region Q11 and a second pixel region Q12, the first pixel region Q11 includes a first main light-emitting device 111 and a first compensating structure 21, and the second pixel region Q12 includes a first main light-emitting device 111 and a first redundant light-emitting device 121. In the first direction a, a distance between the adjacent first main light-emitting devices 111 in the first pixel region Q11 and the first compensating structure 21 is d1; in the first direction a, a distance between the adjacent first main light-emitting devices 111 in the second pixel region Q12 and the first redundant light-emitting device 121 is d2; d1=d2. In FIG. 10, the redundant light-emitting devices 12 outside the first color pixel region Q1 are all filled with the same filling.

The first pixel region Q11 and the second pixel region Q12 are pixel regions displaying the same color, and d1=d2, so the relative position relationship between the first compensating structure 21 and the first main light-emitting device 111 is substantially the same as the relative position relationship between the first redundant light-emitting device 121 and the first main light-emitting device 111. Moreover, orthographic projections of the first compensating structure 21 and the first main light-emitting device 111 on the plane where the substrate is located have the same shape and the same area. The first compensating structure 21 in the first pixel region Q11 is used as a substitute for the first redundant light-emitting device 121, and the first compensating structure 21 may be regarded as a non-light-emitting device, so that the distribution of devices in the first pixel region Q11 is the same as that in the second pixel region Q12. In the manufacturing process of the black adhesive layer 30, the flowing and covering conditions of the black glue material between the first compensating structure 21 and the first main light-emitting device 111 and between the first main light-emitting device 111 and the first redundant light-emitting device 121 can be basically the same, thereby further improving the covering uniformity of the black adhesive layer 30.

In some embodiments, as shown in FIG. 10, in the first pixel region Q11, the first main light-emitting device 111 and the first compensating structure 21 are aligned along the first direction a. The relative position relationship between the first compensating structure 21 and the first main light-emitting device 111 is the same as the relative position relationship between the first redundant light-emitting device 121 and the first main light-emitting device 111. With such arrangement, the positional relationship between the first compensating structure 21 and the adjacent device in the second direction b (the second direction b intersects the first direction a) can be substantially the same as the positional relationship between the first redundant light-emitting device 121 and the adjacent device. In the manufacturing process of the black adhesive layer 30, the flowability of the black glue material around the first compensating structure 21 is substantially the same as the flowability of the black glue material around the first redundant light-emitting device 121, so that the coverage of the black adhesive layer 30 around the first compensating structure 21 is substantially the same as the coverage of the black adhesive layer 30 around the first redundant light-emitting device 121. Therefore, the coverage uniformity of the black adhesive layer 30 can be further improved.

In some embodiments, FIG. 11 is a partial schematic diagram of another display panel according to an embodiment of the present disclosure, as shown in FIG. 11, the compensating structure 20 includes a second compensating structure 22, the main light-emitting device 11 includes a second main light-emitting device 112, and a light-emitting color of the second main light-emitting device 112 is different from a light-emitting color of the first main light-emitting device 111. The orthographic projection area of the first main light-emitting device 111 on the substrate is greater than the orthographic projection area of the second main light-emitting device 112 on the substrate, and the orthographic projection area of the first compensating structure 21 on the substrate is greater than the orthographic projection area of the second compensating structure 22 on the substrate. In FIG. 11, the first compensating structure 21 and the second compensating structure 22 are generally made of the same material, so they are filled in the same way.

The first main light-emitting device 111 and the second main light-emitting device 112 includes different light-emitting materials, the light-emitting colors of the two are different, and the light-emitting efficiencies of the two are different. The orthographic projection area of the first main light-emitting device 111 on the substrate is provided to be larger than the orthographic projection area of the second main light-emitting device 112 on the substrate, thereby compensating the difference in light-emitting efficiency between the first main light-emitting device 111 and the second main light-emitting device 112. According to the size of the first main light-emitting device 111 and the size of the second main light-emitting device 112, the first compensating structure 21 and the second compensating structure 22 with corresponding sizes are provided, and in the manufacturing process of the black adhesive layer 30, the flowability of the black glue material around the first compensating structure 21 is substantially the same as the flowability of the black glue material around the first main light-emitting device 111, and the flowability of the black glue material around the second compensating structure 22 is substantially the same as the flowability of the black glue material around the second main light-emitting device 112, so that the coverage uniformity of the black adhesive layer 30 can be further improved.

In the embodiment of the present disclosure, the light-emitting colors of the first main light-emitting device 111 and the second main light-emitting device 112 are different, and the light-emitting efficiency of the first main light-emitting device 111 is smaller than that of the second main light-emitting device 112. A wavelength of light emitted by the first main light-emitting device 111 is greater than a wavelength of light emitted by the second main light-emitting device 112. For example, the first main light-emitting device 111 emits red light, and the second main light-emitting device 112 emits green light or blue light.

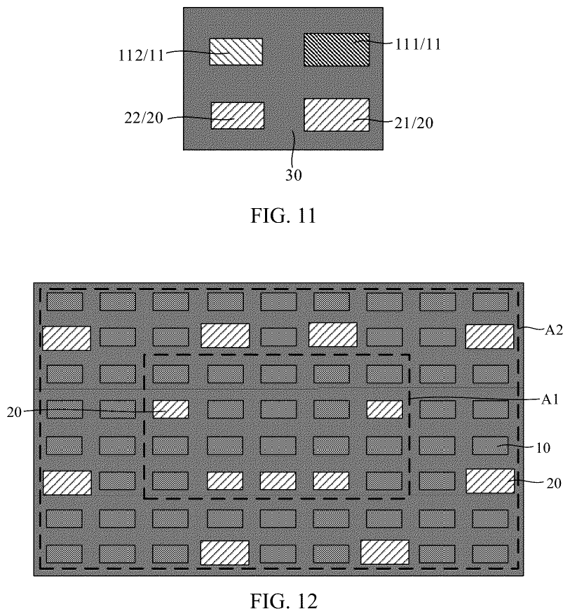

In some embodiments, FIG. 12 is a schematic diagram of another display panel according to an embodiment of the present disclosure, as shown in FIG. 12, the display panel includes a first region A1 and a second region A2, the second region A2 at least partially surrounds the first region A1, and an orthographic projection area of the compensating structure 20 in the second region A2 on the substrate is greater than an orthographic projection area of the compensating structure 20 in the first region A1 on the substrate. The second region A2 is located in the peripheral area of the first region A1, and the size of the compensating structure 20 in the second region A2 is relatively large, so that in the manufacturing process of the black adhesive layer 30, the compensating structure 20 in the second region A2 has a stronger binding ability to the black glue material, thereby preventing the black glue material from overflowing outwards and improving the product yield.

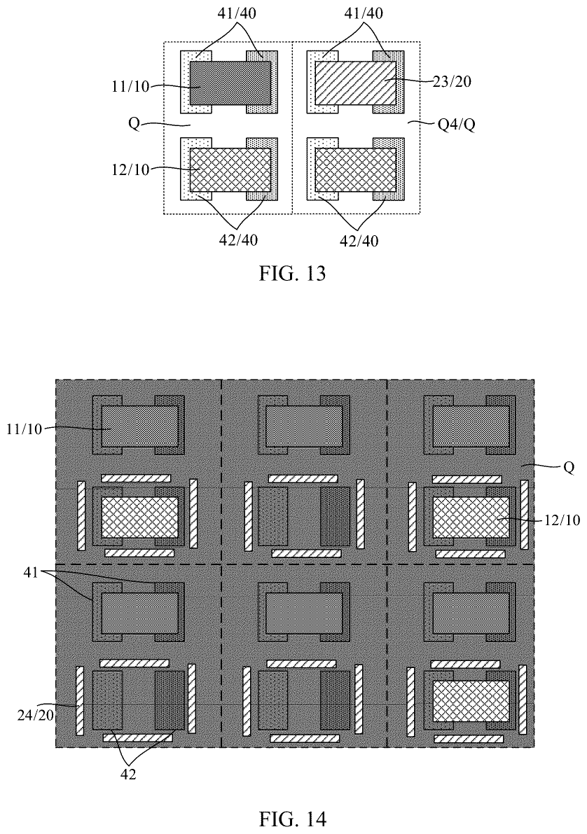

In some embodiments, FIG. 13 is a partial schematic diagram of another display panel according to an embodiment of the present disclosure, as shown in FIG. 13, the pixel region Q in the display panel includes a third pixel region Q4; in the third pixel region: the redundant light-emitting device 12 is connected to the redundant electrode unit 42, and the third compensating structure 23 at least partially overlaps with the main electrode unit 41 in a direction perpendicular to the plane where the substrate is located. The black adhesive layer 30 is not illustrated in FIG. 13. The relative positions of the main electrode unit 41 and the redundant electrode unit 42 in the pixel region Q of the display panel are fixed, and when manufacturing the display panel, the main light-emitting device 11 is first transferred at the position of the main electrode unit 41. Due to the yield problem, the main light-emitting device 11 in some areas may be missing, and when the main light-emitting device 11 cannot be transferred again due to the abnormal transfer above the main electrode unit 41, that is, the third pixel region Q4. In this case, the redundant light-emitting device 12 may be transferred at the redundant position where the redundant electrode unit 42 is located, and the third pixel region Q4 emits light by using the redundant light-emitting device 12. In addition, the third compensating structure 23 is manufactured at the position of the main electrode unit 41 in the third pixel region Q4, and the third compensating structure 23 is filled at the position of the vacant light-emitting device, so that the problem of uneven distribution of the light-emitting devices 10 in the display area can be compensated by using the third compensating structure 23, the coverage uniformity of the black adhesive layer 30 is improved, and the problem of uneven display caused by uneven coverage of the black glue is improved.

As shown in FIG. 14, the display panel includes a main electrode unit 41 and a

redundant electrode unit 42, and the main light-emitting device 11 is connected to the main electrode unit 41. The compensating structure 20 includes a fourth compensating structure 24, and along a direction perpendicular to the plane where the substrate is located, the fourth compensating structure 24 does not overlap with the redundant electrode unit 42. In addition, a plurality of pixel regions Q is defined by dotted lines crossing each other in FIG. 14. If the fourth compensating structure 24 is provided around the redundant electrode unit 42 and does not overlap with the redundant electrode unit 42, the fourth compensating structure 24 does not affect the transfer of the light-emitting device on the redundant electrode unit 42, and can also be used to compensate the problem of uneven distribution of the light-emitting device. When manufacturing the black adhesive layer 30, the black glue material can be gathered around the light-emitting device 10 and the compensating structure 20 under the influence of surface tension in the flowing process, so that the black adhesive layer 30 can be relatively uniformly covered between the compensating structure 20 and the light-emitting device 10 and between adjacent light-emitting devices 10, thereby improving the problem of uneven display caused by uneven coverage of the black glue.

The height of the fourth compensating structure 24 is not greater than the height of the main light-emitting device 11.

An embodiment of the present disclosure further provides a method for manufacturing a display panel, which can be used to manufacture the display panel according to the embodiment of FIG. 14. The manufacturing method includes:

Step S301: forming a main electrode unit 41, a redundant electrode unit 42 and a fourth compensating structure 24 on a side of the substrate 00, with the plane where substrate is located as a reference plane, the height of the fourth compensating structure 24 is higher than that of the main electrode unit 41 and the redundant electrode unit 42, and the fourth compensating structure 24 does not overlap with the redundant electrode unit 42;

Step S302: transferring the main light-emitting device 11 on a side of the substrate 00, the main light-emitting device 11 is connected to the main electrode unit; and

Step S303: forming a black adhesive layer 30, the black adhesive layer 30 is at least filled between adjacent main light-emitting devices 11 and between the adjacent fourth compensating structures 24 and the main light-emitting device 11.

In this embodiment, the fourth compensating structure 24 is manufactured before the light-emitting device is transferred, and the fourth compensating structure 24 may be manufactured by using the process of the driving layer in the display panel. For example, the driving layer includes a planarization layer with a relatively thick thickness, and when manufacturing the planarization layer, the planarization layer may be manufactured by using a half-grayscale mask process and the fourth compensating structure 24 is simultaneously formed, so that the fourth compensating structure 24 has a certain height.

After the main light-emitting device 11 is transferred, the repair position and the compensation position on the display panel can be determined only after the brightness detection is performed on the main light-emitting device 11, that is, there is uncertainty in the compensation position on the display panel. As shown in FIG. 13, a fourth compensating structure 24 is provided near each of the redundant electrode units 42, so that the fourth compensating structure 24 can perform pre-complementing near each of the redundant electrode units 42. After the redundant light-emitting device 12 is transferred at the determined repair position, the fourth compensating structure 24 can finally play a role of compensating the uneven distribution of the light-emitting device 10 near the redundant electrode unit 42 of the non-transferred redundant light-emitting device 12.

FIG. 14 is a schematic top view of a display panel, and it can be seen from FIG. 14 that the orthographic projection area of the fourth compensating structure 24 on the plane of the substrate is smaller than the orthographic projection area of the main light-emitting device 11 on the plane of the substrate. That is, the size of the fourth compensating structure 24 is smaller than the size of the main light-emitting device 11. Since the fourth compensating structure 24 is provided between the main electrode unit 41 and the redundant electrode unit 42, the size of the single fourth compensating structure 24 is small, which is beneficial to reducing the space occupation of the fourth compensating structure 24 and avoiding the fourth compensating structure 24 from affecting the transfer process of the light-emitting device.

In some embodiments, as shown in FIG. 14, the plurality of fourth compensating structures 24 are at least partially provided surrounding the redundant electrode unit 42. In this way, the total area of the compensating structure 20 around the redundant electrode unit 42 can be increased, thereby improving the compensation ability of the compensating structure 20 to compensate the distribution uniformity of the light-emitting device 10. The number of the fourth compensating structures 24 provided surrounding the redundant electrode unit 42 is not limited.

In some other embodiments, the fourth compensating structure 24 forms a closed cyclic structure around the redundant electrode unit 42, that is, the fourth compensating structure 24 around the redundant electrode unit 42 is integrally connected, which will not be illustrated here.

As shown in FIG. 14, the light-emitting device 10 further includes a redundant light-emitting device 12, and the redundant light-emitting device 12 is connected to the redundant electrode unit 42; and along a direction perpendicular to the plane where the substrate is located, the fourth compensating structure 24 does not overlap with the redundant light-emitting device 12. The arrangement of the fourth portion structure 24 does not affect the transfer yield of the redundant light-emitting device 12, and meanwhile, the fourth portion structure 24 can also function to compensate the distribution uniformity of the light-emitting device 10 at a position where the redundant light-emitting device 12 is not provided.

In some embodiments, the light-emitting device 10 includes light-emitting devices of three colors: red, green, and blue. The heights of the three-color light-emitting devices may be the same or different. The height of the fourth compensating structure 24 is not greater than the height of the light-emitting device adjacent thereto.

As shown in FIG. 14, the distance between the fourth compensating structure 24 and the redundant electrode unit 42 is smaller than the distance between the fourth compensating structure 42 and the main electrode unit 41, that is, the distance between the fourth compensating structure 24 and the redundant electrode unit 42 is closer. The redundant electrode unit 42 is located at a redundant position corresponding to the main electrode unit 41, and when the redundant light-emitting device 12 is transferred at a part of the redundant position, the part of the redundant electrode unit 42 replaces the main electrode unit 41 to work. When there is no redundant light-emitting device 12 transferred at the redundant position, there is a light-emitting device vacancy at the position of the redundant electrode unit 42, resulting in uneven distribution of the entire light-emitting device 10. In the embodiments of the present disclosure, the fourth compensating structure 24 is provided closer to the redundant electrode unit 42, so that the distribution uniformity of the light-emitting device 10 can be compensated at a position where the redundant electrode unit 42 of the redundant light-emitting device 12 is not provided.

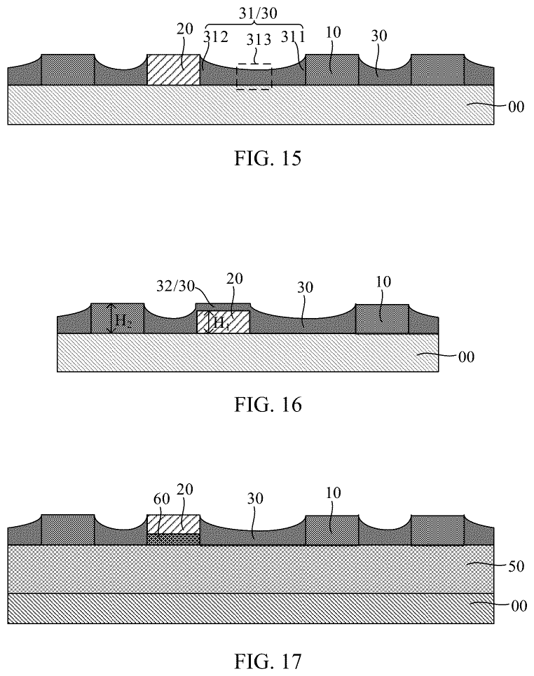

In some embodiments, FIG. 15 is a schematic cross-sectional view of another display panel according to an embodiment of the present disclosure, as shown in FIG. 15, the black adhesive layer 30 includes a first section 31, and the first section 31 is located between the adjacent light-emitting device 10 and compensating structure 20; the first section 31 includes a first end portion 311, a second end portion 312, and a middle portion 313 located between the first end portion 311 and the second end portion 312; the first end portion 311 is adjacent to the light-emitting device 10, and the second end portion 312 is adjacent to the compensating structure 20. A vertical distance between a surface of the middle portion 313 away from the substrate 00 and the substrate 00 is a first distance, a vertical distance between a surface of the first end portion 311 away from the substrate 00 and the substrate 00 is a second distance, and a vertical distance between a surface of the second end portion 312 away from the substrate 00 and the substrate 00 is a third distance; the first distance is smaller than the second distance, and/or the first distance is smaller than the third distance. In the manufacturing process of the black adhesive layer 30, the black glue material has a certain fluidity, and the black glue material will be gathered around the light-emitting device 10 and the compensating structure 20 under the influence of surface tension, so that the height of the first end portion 311 adjacent to the light-emitting device 10 (the height is taken with the plane where the substrate 00 is located as the reference plane) will be relatively large, the height of the second end portion 312 adjacent to the compensating structure 20 will also be relatively large, and the height of the middle portion 313 will be relatively small. In a direction from the light-emitting device 10 to the adjacent compensating structure 20, the height variation trend of the first section 31 is gradually decreasing and then gradually increasing. As shown in FIG. 15, the variation trend of the height of the black adhesive layer 30 between two adjacent light-emitting devices 10 in the cross-sectional view is gradually decreasing and then gradually increasing.

In some embodiments, in a direction perpendicular to the plane where the substrate 00 is located, the thickness of the black adhesive layer 30 is 2 μm to 8 μm. Optionally, a difference between the second distance and the first distance in the first section 31 is ≤3 μm, and a difference between the third distance and the first distance is ≤3 μm. In this way, the height difference between the two end portions of the first section 31 and the middle portion 313 is small, the film thickness uniformity of the first section 31 can be improved, the black consistency of the black adhesive layer 30 is good, and the contrast is improved.

In some embodiments, the difference between the surface tension of the interface between the black glue material and the compensating structure 20 and the surface tension of the interface between the black glue material and the light-emitting device 10 is not large, and the second distance is equal to the third distance. In this way, the film thickness uniformity of the first section 31 can be further improved, which is beneficial to improving the contrast.

In some embodiments, FIG. 16 is a schematic cross-sectional view of another display panel provided by an embodiment of the present disclosure, as shown in FIG. 16, a vertical distance between a surface of a side of the compensating structure 20 away from the substrate 00 and the substrate 00 is H₁, a vertical distance between a surface of a side of the light-emitting device 10 away from the substrate 00 and the substrate 00 is H₂, H₁<H₂, the black adhesive layer 30 further includes a second section 32, and the second section 32 covers the compensating structure 20 on a side of the compensating structure 20 away from the substrate 00. In this embodiment, the height of the compensating structure 20 is lower than the height of the light-emitting device 10, and when the black adhesive layer 30 is manufactured, the compensating structure 20 is covered by the black adhesive layer 30, so that the areas except the light-emitting device 10 in the display area are covered by the black adhesive layer 30, thereby improving the display contrast.

In some embodiments, FIG. 17 is a schematic cross-sectional view of another display panel according to an embodiment of the present disclosure. As shown in FIG. 17, the display panel further includes a driving layer 50, the driving layer 50 is located between the light-emitting device 10 and the substrate 00, and a pixel circuit is provided in the driving layer 50, the electrode unit according to the above embodiment is manufactured in the driving layer 50. The driving layer 50 is only simply shown in FIG. 17. The compensating structure 20 is bonded to the driving layer 50 through the bonding layer 60. The display panel in this embodiment may be manufactured by using the manufacturing method provided in the embodiment of FIG. 3. After the light-emitting device 10 is transferred on a side of the driving layer 50, the compensation position is determined by brightness detection, and then the position of the compensating structure 20 is fixed by using the bonding layer 60. The bonding layer 60 may be a solder or an adhesive.

In some embodiments, the compensating structure 20 includes a black material, and the black material is an organic material or an inorganic material. In this embodiment, the compensating structure 20 is black, which can reduce the surface reflectivity of the compensating structure 20. The compensating structure 20 and the black adhesive layer 30 are substantially different visually, so that the areas in the display area except the light-emitting device 10 are black, thereby improving the display contrast.

In some embodiments, the compensating structure 20 includes the same material as the materials of the light-emitting device 10, such as a semiconductor material such as GaN. This arrangement can make the surface tension of the contact interface between the black glue material and the compensating structure 20 substantially the same as the surface tension of the contact interface between the black glue material and the light-emitting device 10, further improving the coverage uniformity of the black adhesive layer 30.

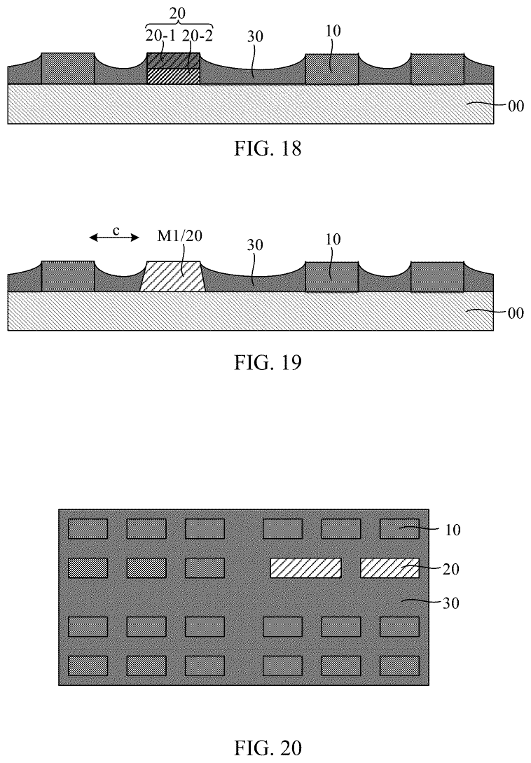

In some other embodiments, FIG. 18 is a schematic cross-sectional view of another display panel according to an embodiment of the present disclosure. As shown in FIG. 18, the compensating structure 20 includes a first layer 20-1 and a second layer 20-2 that are stacked, the first layer 20-1 is located on a side of the second layer 20-2 away from the substrate 00, and the first layer 20-1 includes a black material. In this embodiment, the compensating structure 20 includes at least two film layers, and the uppermost layer on the side away from the substrate 00 is provided to include a black material, which can reduce the surface reflectivity of the compensating structure 20. The compensating structure 20 and the black adhesive layer 30 are substantially different visually, so that the areas in the display area except the light-emitting device 10 are black, thereby improving the display contrast.

In some other embodiments, FIG. 19 is a schematic cross-sectional view of another display panel according to an embodiment of the present disclosure, as shown in FIG. 19, the compensating structure 20 has a first cross section M1, the first cross section MI is perpendicular to a plane where the substrate 00 is located, a width of the first cross section MI along the third direction c is a first width, and the third direction c is parallel to a direction where the substrate 00 is located; and the first width gradually increasing in a direction from the compensating structure 20 to the substrate 00. With such arrangement, the black glue material in contact with the periphery of the compensating structure 20 can be more easily irradiated by light during manufacturing, and the black glue material is easily completely cured, thereby improving the manufacturing yield of the black adhesive layer 30. In addition, during manufacturing, the black glue material on the side away from the substrate 00 flows faster, and the black glue material on the side close to the substrate 00 flows relatively slowly, the change rule of variation of the first width in this embodiment is designed to avoid the formation of air bubbles in the black glue material close to the side of the substrate 00, and thus to avoid the rupture of the air bubbles from affecting the uniformity of the coverage of the black adhesive layer 30.

FIG. 19 shows that the first cross section M1 is a regular trapezoid, that is, an interface of the compensating structure 20 in contact with the black adhesive layer 30 is substantially a plane. In some embodiments, an interface between the compensating structure 20 and the black adhesive layer 30 is a curved surface, and the first width gradually increasing in a direction from the compensating structure 20 to the substrate 00, which is not illustrated herein.

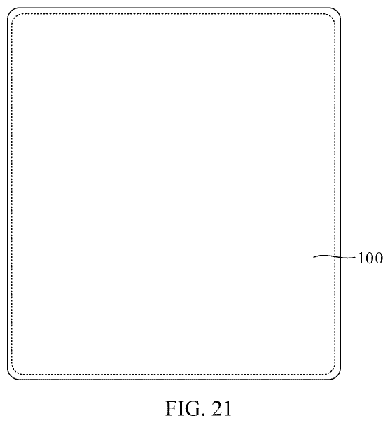

In some embodiments, FIG. 20 is a schematic diagram of another display panel according to an embodiment of the present disclosure, as shown in FIG. 20, the orthographic projection area of the compensating structure 20 in the plane where the substrate is located is larger than the orthographic projection area of the light-emitting device 10 in the plane where the substrate is located. Optionally, one compensating structure 20 overlaps with two or more redundant electrode units.

Based on the same inventive concept, an embodiment of the present disclosure further provides a display device, FIG. 21 is a schematic diagram of a display device according to an embodiment of the present disclosure, and as shown in FIG. 21, the display device includes the display panel 100 according to any embodiment of the present disclosure. The structure of the display panel 100 has been described in the above embodiments, and will not be repeated here.

The display device provided by the embodiments of the present disclosure may be, for example, an electronic device having a display function, such as a mobile phone, a tablet, a computer, a television, a vehicle-mounted display, a billboard, and an intelligent wearable device.

The above description is only a preferred embodiment of the present disclosure and is not intended to limit the present disclosure, and any modifications, equivalent substitutions, improvements and the like made within the spirit and principle of the present disclosure should be included within the scope of the present disclosure.

Finally, it should be noted that: The above embodiments are only used to illustrate the technical solutions of the present disclosure, but not to limit the same; although the present disclosure has been described in detail with reference to the above embodiments, those skilled in the art should understand that: The technical solutions described in the above embodiments may still be modified, or some or all of the technical features may be equivalently replaced; and these modifications or substitutions do not make the essence of the corresponding technical solutions depart from the scope of the technical solutions in the embodiments of the present disclosure.

What is claimed is:

1. A display panel, comprising:
a substrate;
a light-emitting device and a compensating structure located on a side of the substrate and located in a display area; and
a black adhesive layer located on a side of the substrate, wherein the black adhesive layer is at least filled between adjacent light-emitting devices and between the compensating structure and the light-emitting device that are adjacent to each other.

2. The display panel according to claim 1, further comprising:
an electrode unit provided on a side of the substrate, wherein the electrode unit comprises a main electrode unit and a redundant electrode unit;
wherein the light-emitting device comprises a main light-emitting device, the main light-emitting device is connected to the main electrode unit; and
wherein the compensating structure at least partially overlaps with the redundant electrode unit in a direction perpendicular to a plane where the substrate is located.

3. The display panel according to claim 2, wherein, the compensating structure comprises a first compensating structure, and the main light-emitting device comprises a first main light-emitting device; and
wherein an orthographic projection area of the first compensating structure on the substrate is equal to an orthographic projection area of the first main light-emitting device on the substrate.

4. The display panel according to claim 3, wherein, an orthographic projection of the first compensating structure on the substrate has a same shape as an orthographic projection of the first main light-emitting device on the substrate.

5. The display panel according to claim 4, wherein, the light-emitting device further comprises a redundant light-emitting device connected to the redundant electrode unit; the redundant light-emitting device comprises a first redundant light-emitting device, and a light-emitting material of the first redundant light-emitting device is the same as a light-emitting material of the first main light-emitting device;
wherein the display panel further comprises pixel regions, one of the pixel regions comprises first color pixel regions, one of the first color pixel regions comprises a first pixel region and a second pixel region, the first pixel region comprises the first main light-emitting device and the first compensating structure, and the second pixel region comprises the first main light-emitting device and the first redundant light-emitting device;
wherein, in a first direction, a distance between the adjacent first main light-emitting devices and first compensating structure in the first pixel region is represented as d1; in the first direction, a distance between the adjacent first main light-emitting device and first redundant light-emitting device in the second pixel region is represented as d2; where d1=d2.

6. The display panel according to claim 5, wherein, in the first pixel region, the first main light-emitting device and the first compensating structure are aligned along the first direction.

7. The display panel according to claim 3, wherein, the compensating structure comprises a second compensating structure, the main light-emitting device comprises a second main light-emitting device, and a light-emitting color of the second main light-emitting device is different from a light-emitting color of the first main light-emitting device;
wherein an orthographic projection area of the first main light-emitting device on the substrate is greater than an orthographic projection area of the second main light-emitting device on the substrate, and an orthographic projection area of the first compensating structure on the substrate is greater than an orthographic projection area of the second compensating structure on the substrate.

8. The display panel according to claim 2, further comprising a first region and a second region, and the second region at least partially surrounds the first region,
wherein an orthographic projection area of the compensating structure in the second region on the substrate is greater than an orthographic projection area of the compensating structure in the first region on the substrate.

9. The display panel according to claim 1, further comprising: an electrode unit provided on a side of the substrate, wherein the electrode unit comprises a main electrode unit and a redundant electrode unit;
wherein the light-emitting device comprises a main light-emitting device, and the main light-emitting device is connected to the main electrode unit; and
wherein the compensating structure comprises a fourth compensating structure, and the fourth compensating structure does not overlap with the redundant electrode unit in a direction perpendicular to a plane of the substrate.

10. The display panel according to claim 9, wherein, a plurality of fourth compensating structures is provided and at least partially surround the redundant electrode unit; and/or,
wherein, a distance between the fourth compensating structure and the redundant electrode unit is smaller than a distance between the fourth compensating structure and the main electrode unit.

11. The display panel according to claim 1, wherein, the black adhesive layer comprises a first section, and the first section is located between the light-emitting device and the compensating structure that are adjacent to each other; the first section comprises a first end portion, a second end portion, and an intermediate portion located between the first end portion and the second end portion; the first end portion is adjacent to the light-emitting device, and the second end portion is adjacent to the compensating structure;
wherein a vertical distance from a surface of the middle portion away from the substrate to the substrate is represented as a first distance, a vertical distance from a surface of the first end portion away from the substrate to the substrate is represented as a second distance, and a vertical distance from a surface of the second end portion away from the substrate to the substrate is represented as a third distance; and,
wherein the first distance is smaller than the second distance, and/or, the first distance is smaller than the third distance; and/or,
wherein, the second distance is equal to the third distance.

12. The display panel according to claim 1, wherein a vertical distance between a surface of the compensating structure away from the substrate and the substrate is represented as H₁, and a vertical distance between a surface of the light-emitting device away from the substrate and the substrate is represented as H₂, where H₁≤H₂.

13. The display panel according to claim 12, wherein H₁<H₂, the black adhesive layer further comprises a second section, and the second section covers the compensating structure on a side of the compensating structure away from the substrate.

14. The display panel according to claim 1, further comprising a driving layer located between the light-emitting device and the substrate,
wherein the compensating structure is bonded to the driving layer through a bonding layer.

15. The display panel according to claim 1, wherein the compensating structure comprises a black material.

16. The display panel according to claim 15, wherein the compensating structure comprises a first layer and a second layer which are stacked, the first layer is located on the side of the second layer away from the substrate, and the first layer comprises the black material.

17. The display panel according to claim 1, wherein the compensating structure has a first cross section, the first cross section is perpendicular to a plane of the substrate, a width of the first cross section along a third direction is a first width, and the third direction is parallel to a direction where the substrate is located; and
wherein the first width gradually increases in a direction from the compensating structure to the substrate.

18. A method for manufacturing a display panel, wherein the display panel comprises a light-emitting device and a compensating structure, and the method comprises:
transferring at least part of the light-emitting device on a side of the substrate;
detecting a brightness of the light-emitting device and determining the compensation position;
manufacturing a corresponding compensating structure according to the compensation position; and
forming a black adhesive layer, wherein the black adhesive layer is at least filled between the adjacent light-emitting devices and between the adjacent compensating structure and light-emitting device.

19. The method according to claim 18, wherein the light-emitting device comprises a main light-emitting device and a redundant light-emitting device, and
wherein the method further comprises forming an electrode unit on a side of a substrate before transferring at least part of the light-emitting device on the side of the substrate, wherein the electrode unit comprises a main electrode unit and a redundant electrode unit;
wherein transferring at least part of the light-emitting device on a side of the substrate comprises: transferring the main light-emitting device on a side of the substrate, the main light-emitting device is connected to the main electrode unit;
wherein detecting the brightness of the light-emitting device and determining the compensation position comprises: detecting brightness of the main light-emitting device to determine a position of a defective light-emitting device, and determining a repair position and the compensation position according to the position of the defective light-emitting device; and
the method further comprises, before manufacturing the corresponding repair structure according to the repair position, manufacturing the corresponding redundant light-emitting device according to the repair position, the redundant light-emitting device is connected to the redundant electrode unit;
wherein manufacturing the corresponding compensating structure according to the compensation position comprises the compensating structure at least partially overlaps with the redundant electrode unit.

20. A display device, comprising a display panel, wherein the display panel comprises
a substrate;
a light-emitting device and a compensating structure located on a side of the substrate and located in the display area; and
a black adhesive layer located on a side of the substrate, wherein the black adhesive layer is at least filled between adjacent light-emitting devices and between the compensating structure and the light-emitting device that are adjacent to each other.
